(19) United States
(12) Patent Application Publication
(10) Pub. No.: US 2007/0210339 A1
(43) Pub. Date: Sep. 13, 2007

(54) Shared contact structures for integrated circuits

(76) Inventors: Geethakrishnan Narasimhan, Sunnyvale, CA (US); Bartosz Banachowicz, Santa Clara, CA (US); Ravindra Kapre, San Jose, CA (US)

Correspondence Address: OKAMOTO & BENEDICTO, LLP, P.O. BOX 641330, SAN JOSE, CA, 95164, US

(21) Appl. No.: 11/372,293

(22) Filed: Mar. 9, 2006

(51) Int. Cl. H01L 29/76; H01L 21/8234

(52) U.S. Cl. 257/213; 438/197

(57) ABSTRACT

In one embodiment, a shared contact structure electrically connects a gate, a diffusion region, and another diffusion region. The shared contact structure may comprise a trench that exposes the gate, the diffusion region, and the other diffusion region. The trench may be filled with a metal to form electrical connections. The trench may be formed in a dielectric layer using a self-aligned etch step, for example.

### BACKGROUND OF THE INVENTION

1. Field of the Invention

The present invention relates generally to integrated circuits, and more particularly to integrated circuit fabrication processes and structures.

2. Description of the Background Art

An integrated circuit may be fabricated to include a plurality of transistors having gates and diffusion regions. The gates may be formed using deposition and etching steps, while the diffusion regions may be formed by implantation of the substrate (e.g., silicon substrate). Nodes of an integrated circuit may be connected together using interconnect lines. For example, a gate and a diffusion region of a transistor may be electrically tied together by way of overlying metal lines and via connections. Although currently available integrated circuits are relatively small, the search for even smaller integrated circuits continues. Therefore, techniques for connecting various nodes of an integrated circuit using relatively small areas are generally desirable. Preferably, these techniques minimize processing steps and do not negatively impact the performance and reliability of the integrated circuit.

### SUMMARY

In one embodiment, a shared contact structure electrically connects a gate, a diffusion region and another diffusion region. The shared contact structure may comprise a trench that exposes the gate, the diffusion region, and another diffusion region. The trench may be filled with a metal to form electrical connections. The trench may be formed in a dielectric layer using a self-aligned etch step, for example.

These and other features of the present invention will be readily apparent to persons of ordinary skill in the art upon reading the entirety of this disclosure, which includes the accompanying drawings and claims.

### DESCRIPTION OF THE DRAWINGS

FIG. 1 shows a layout view of an integrated circuit.

FIG. 2A shows a layout view of another integrated circuit.

FIG. 2B schematically shows a cross-sectional view of the integrated circuit of FIG. 2A.

FIGS. 3A, 3B, and 3C show layout views of an integrated circuit in accordance with an embodiment of the present invention.

FIG. 3D schematically shows a cross-sectional view of the integrated circuit of FIG. 3A.

FIG. 3E schematically shows another cross-sectional view of the integrated circuit of FIG. 3A.

FIGS. 4A-4D schematically show cross-sectional views of an integrated circuit being fabricated to include a shared contact structure.

FIGS. 5A-5F schematically show cross-sectional views of an integrated circuit being fabricated to include a shared contact structure in accordance with an embodiment of the present invention.

FIG. 6A shows a micrograph image of an integrated circuit with an oxide fence.

FIG. 6B shows a micrograph image of an integrated circuit with a trench structure in accordance with an embodiment of the present invention.

The use of the same reference label in different drawings indicates the same or like components.

### DETAILED DESCRIPTION

In the present disclosure, numerous specific details are provided, such as examples of apparatus, materials, process steps, and structures, to provide a thorough understanding of embodiments of the invention. Persons of ordinary skill in the art will recognize, however, that the invention can be practiced without one or more of the specific details. In other instances, well-known details are not shown or described to avoid obscuring aspects of the invention.

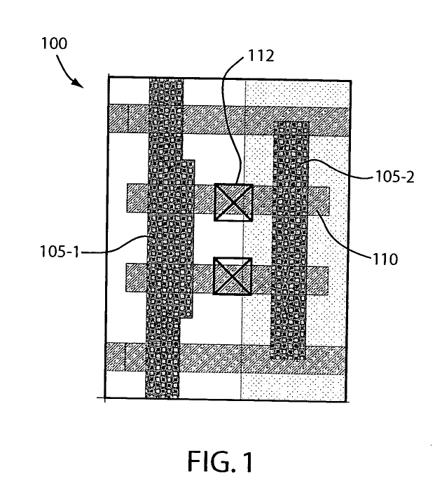

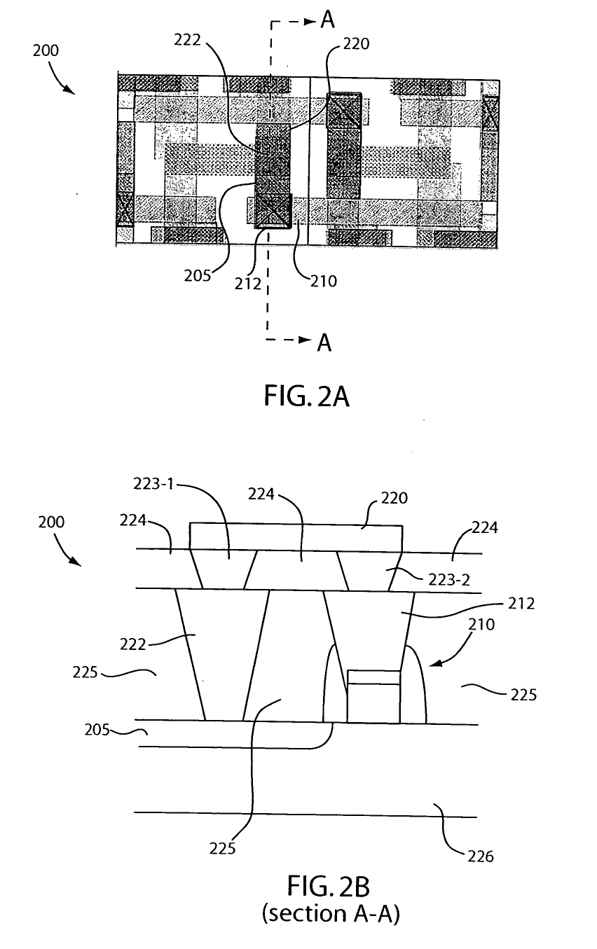

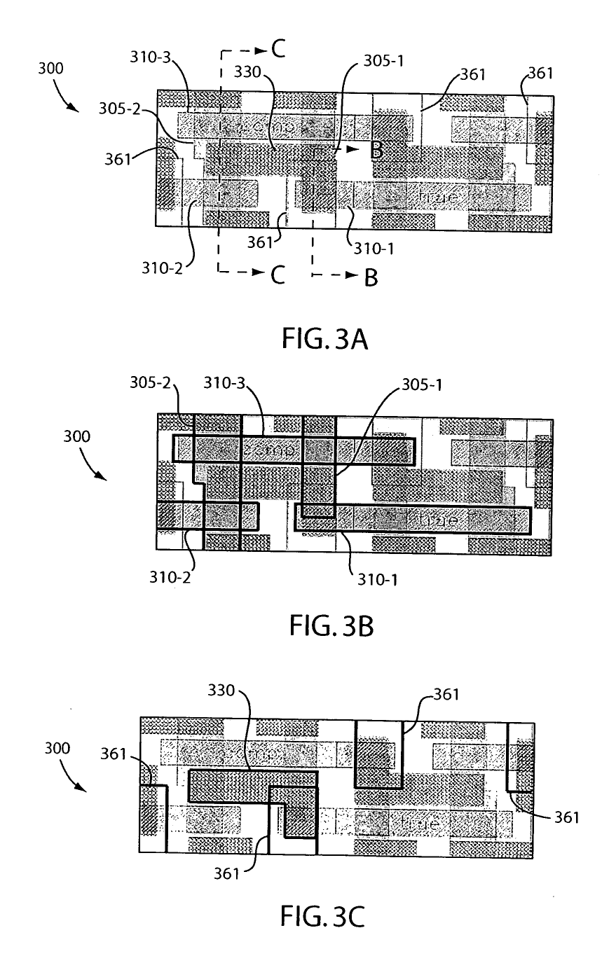

FIG. 1 shows a layout view of an example integrated circuit 100. The integrated circuit 100 includes a gate 110 and diffusion regions 105 (i.e., 105-1, 105-2). Other features of the integrated circuit 100 are not labeled for clarity of illustration. The diffusion regions 105 are also referred to as “active regions,” and may serve as a drain or a source of a transistor. A gate contact structure 112 allows an overlying metal layer to electrically connect to the gate 110. The features of the integrated circuit 100 may be fabricated closer together to make room for more electrical circuits. An example of such an integrated circuit is shown in FIG. 2A.

FIG. 2A shows a layout view of an example integrated circuit 200. In the example of FIG. 2A, the integrated circuit 200 includes a gate 210, a diffusion region 205, a gate contact structure 212, a metal layer 220, and a diffusion region contact structure 222. FIG. 2B schematically shows a cross-sectional view of the integrated circuit 200 taken along section A-A of FIG. 2A. As shown in FIG. 2B, the gate 210 may be formed on a substrate 226. The gate contact structure 212 electrically connects the gate 210 to the metal layer 220 by way of a via connection 223-2. The metal layer 220 electrically shorts the gate 210 to the diffusion region 205 in the substrate 226 by way of a via connection 223-1, the via connection 223-2, and the diffusion region contact structure 222. The via connections 223 (i.e., 223-1, 223-2), gate contact structure 212, and diffusion region contact structure 222 may comprise a metal. The metal layer 220 may be on a local interconnect level.

In the example of FIG. 2B, the gate contact structure 212 and the diffusion region contact structure 222 are formed through a dielectric layer 225, while the via connections 223 are formed through a dielectric layer 224. Note that shorting the gate 210 to its diffusion region 205 requires an electrical connection through at least two levels above the gate 210: the level on which the via connections 223 are formed and the level on which the metal layer 220 is formed.

In one embodiment, a gate shares a contact structure with one or more of its own diffusion regions and another node of the integrated circuit, such as another diffusion region of another transistor, to save space. As will be more apparent below, the shared contact structure may comprise a trench.

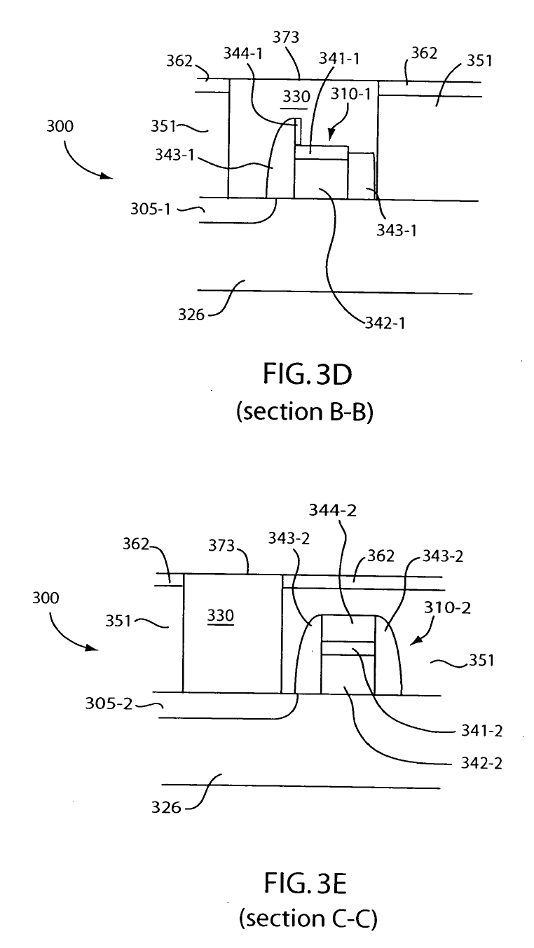

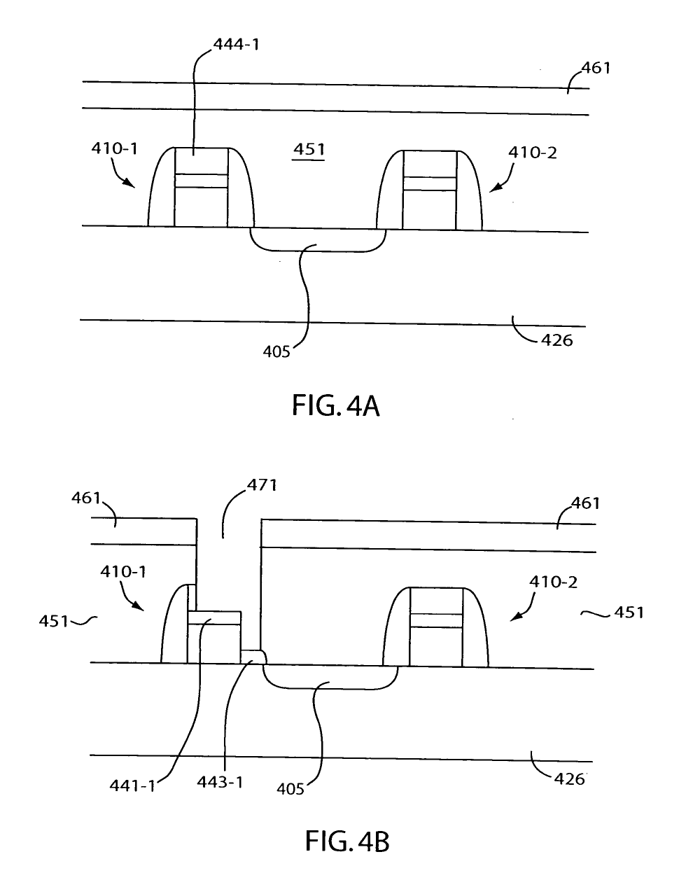

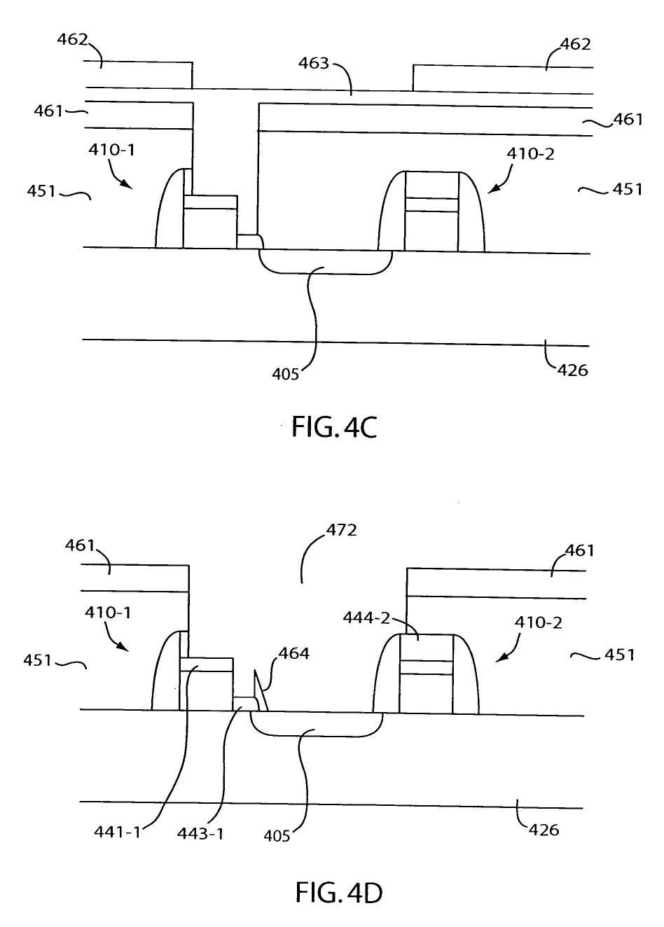

FIG. 3A shows a layout view of an integrated circuit 300 in accordance with an embodiment of the present invention. In the example of FIG. 3A, the integrated circuit 300 includes diffusion regions 305 (i.e., 305-1, 305-2), gates 310 (i.e., 310-1, 310-2, 310-3), and a trench structure 330. As will be more apparent below, the trench structure 330 provides a shared contact structure electrically connecting the diffusion region 305-1, the diffusion region 305-2, and the gate 310-1. In general, the trench structure 330 may connect additional diffusion regions and gates if required by the application. In light of the present disclosure, it can be appreciated that the trench structure 330 may also electrically connect the diffusion region 305-1 and the gate 310-1 to other nodes or features in the integrated circuit 300. FIG. 3A also shows a mask 361 over the layout. The regions enclosed by the mask 361 are those to be etched away to form the shared contact structure.

FIGS. 3B and 3C show the same layout as FIG. 3A except some features of integrated circuit 300 have been highlighted for clarity of illustration. FIG. 3B highlights the gates 310 and the diffusion regions 305. The diffusion region 305-1 may be the active region of a first transistor that includes the gate 310-3 while the diffusion region 305-2 may be the active region of a second transistor that includes the gate 310-2. FIG. 3C highlights the trench structure 330 and the mask 361. The trench structure 330 may be filled with a metal to electrically connect the gate 310-1, the diffusion region 305-1, and the diffusion region 305-2 together. In one embodiment, the trench structure 330 has an L shape. The Trench structure 330 may have other shapes without detracting from the merits of the present invention.

FIG. 3D schematically shows a cross-sectional view of the integrated circuit 300 taken at section B-B of FIG. 3A. The trench structure 330 may be filled with a metal 373 (e.g., tungsten) to electrically connect the gate 310-1 to diffusion region 305-1, which is formed in a substrate 326. The substrate 326 may comprise a semiconductor (e.g. silicon) wafer, for example. The trench structure 330 may be dug through a dielectric layer 351 and a capping layer 362 (e.g., silicon nitride) formed over the gates 310. In the example of FIG. 3D (see also FIG. 3E), a gate 310 (i.e., 310-1, 310-2) may comprise a gate polysilicon 342 (i.e., 342-1, 342-2), a gate metal 341 (i.e., 341-1, 341-2; e.g., tungsten), a gate protective layer 344 (i.e., 344-1, 344-2; e.g., silicon nitride), and sidewalls 343 (i.e., 343-1, 343-2; e.g., silicon nitride). A gate 310 also includes a gate oxide layer (not shown) between a gate polysilicon 342 and the substrate 326. A gate 310 may include other layers of materials without detracting from the merits of the present invention.

In general, a gate protective layer 344 serves an electrical insulator to prevent inadvertent shorting of a gate metal 341, which serves as an electrical conductor of the gate. In the example of FIG. 3D, portions or the entire gate protective layer 344-1 may be etched away to expose the gate metal 341-1 and directly connect it to the diffusion region 305-1 using the trench structure 330. The trench structure 330 advantageously allows for an electrical connection between the gate 310-1 and the diffusion region 305-1 without requiring connection to overlying metal levels.

FIG. 3E schematically shows a cross-sectional view of the integrated circuit 300 taken at section C-C of FIG. 3A. As shown in FIG. 3E, the trench structure 330 directly connects to the diffusion region 305-2. This advantageously allows the trench structure 330 to electrically connect the gate 310-1 and the diffusion region 305-1 of the first transistor to the diffusion region 305-2 of the second transistor. The trench structure 330 is dug through the dielectric layer 351 and the capping layer 362 and filled with the metal 373. The gate 310-2 has the same structure as the gate 310-1.

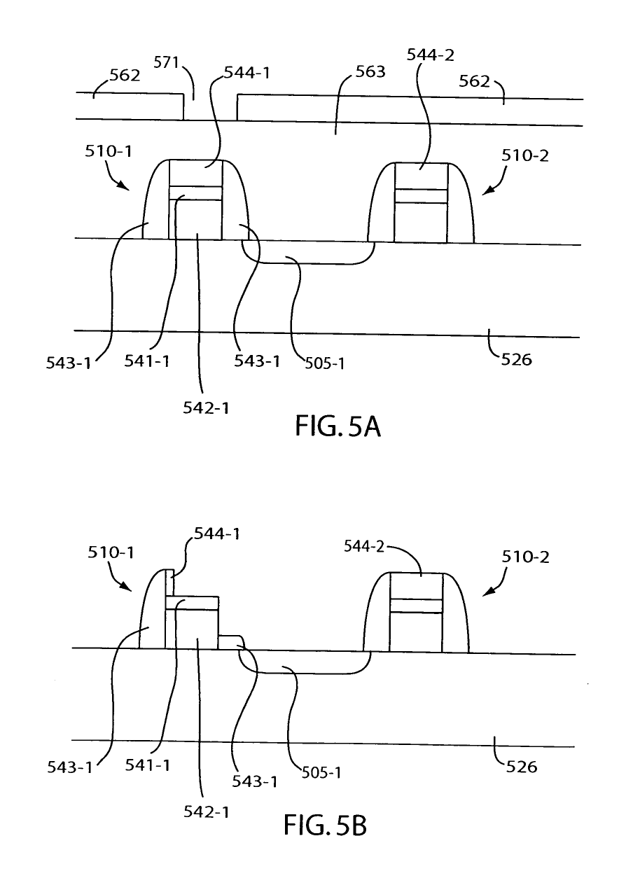

FIGS. 4A-4D schematically show cross-sectional views of an integrated circuit being fabricated to include a shared contact structure. In the example of FIGS. 4A-4D, a single diffusion region 405 shared by gates 410 is shown for illustration purposes only. Different diffusion region configurations may also be employed.

In FIG. 4A, the gates 410 (i.e., 410-1, 410-2) are formed on a substrate 426, which may be a semiconductor wafer. The diffusion region 405 is formed in the substrate 426. Each gate 410 may have the same structure as the previously described gates 310. A dielectric layer 451, which may comprise phosphosilicate glass (PSG), is formed over the gates 410. The dielectric layer 451 is planarized before a capping layer 461 is formed over the dielectric layer 451. The capping layer 461 may comprise silicon nitride or oxide.

In FIG. 4B, the capping layer 461, the dielectric layer 451, and the gate protective layer 444-1 of the gate 410-1 are etched to expose the gate metal 441-1 of the gate 410-1. This allows the gate 410-1 to be electrically connected to another feature of the integrated circuit. A spacer 443-1 is also etched as a result because it comprises the same material as the gate protective layer 444-1 in this example.

In FIG. 4C, an anti-reflective coating (ARC) 463 is formed over the sample of FIG. 4B. The anti-reflective coating 463 may be formed by spin on, for example. A mask 462 is formed over the antireflective coating 463. The mask 462 defines a trench structure 472 (see FIG. 4D).

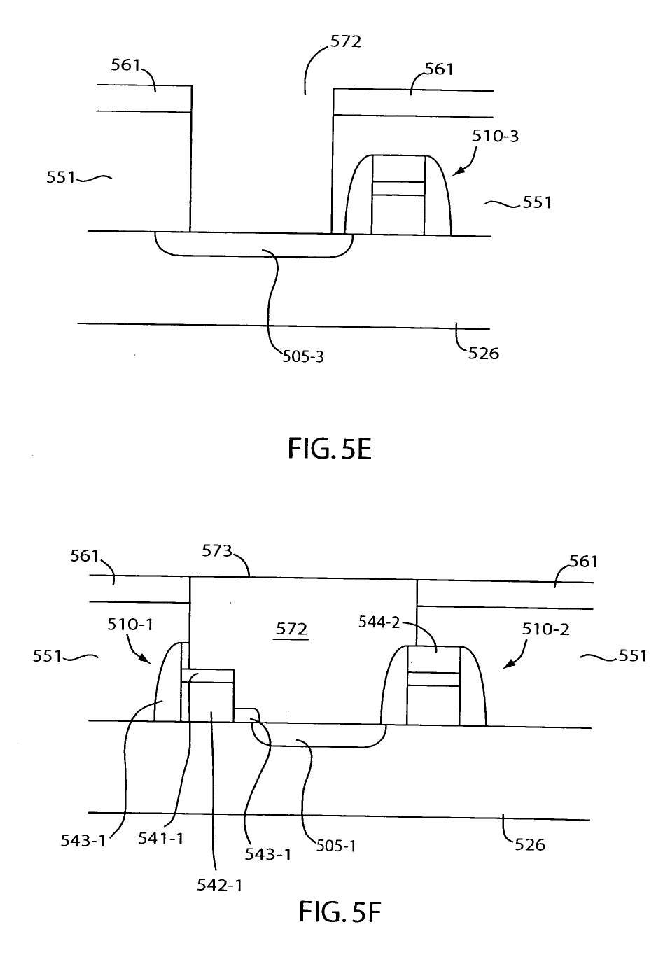

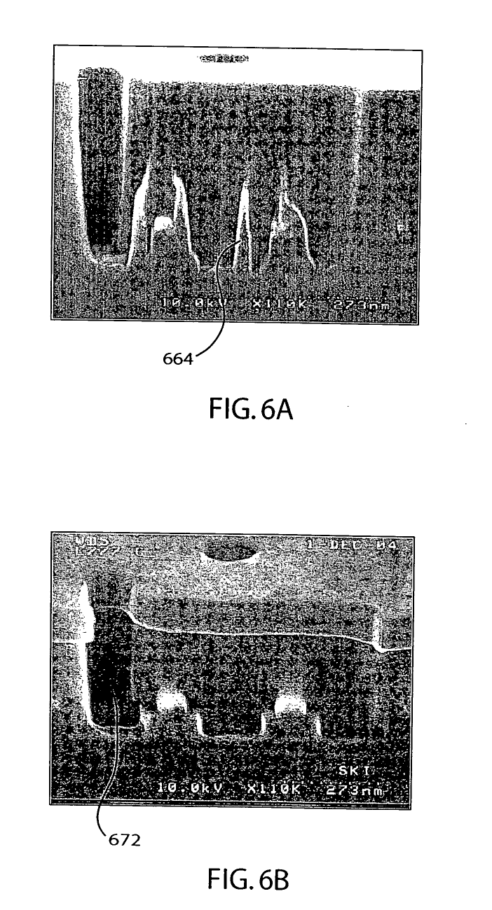

In FIG. 4D, the trench structure 472 is formed, and the antireflective coating 463 and the mask 462 are removed thereafter. In the example of FIG. 4D, the trench structure 472 is formed by etching through the capping layer 461 and the dielectric layer 451. The trench structure 471 exposes the diffusion region 405 and the gate metal 441-1. The trench structure 472 may also expose a diffusion region of another transistor (not shown) in another portion the integrated circuit. The trench structure 472 may be filled with a metal to electrically couple the gate 410-1, the diffusion region 405, and the diffusion region of another transistor not shown in FIG. 4D. Although workable, the just described fabrication method has a tendency to form an oxide fence 464 after the formation of the trench structure 472. The oxide fence 464 may fall and prevent contact formation or result in other reliability problems. FIG. 6A shows a micrograph image of an integrated circuit with an oxide fence 664.

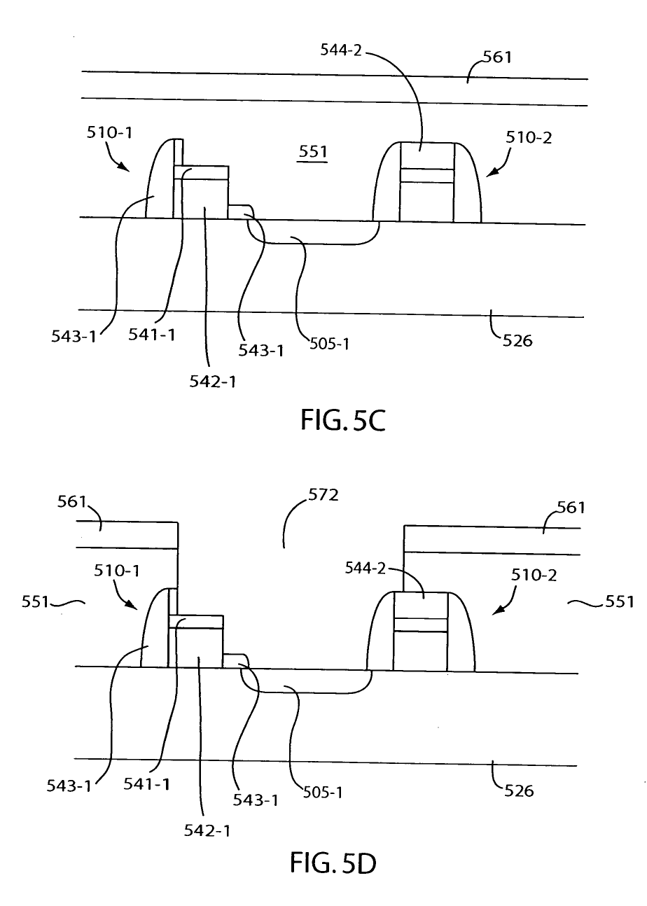

FIGS. 5A-5F schematically show cross-sectional views of an integrated circuit being fabricated to include a shared contact structure in accordance with an embodiment of the present invention. As will be more apparent below, the shared contact structure may comprise a trench. In the example of FIGS. 5A-5F, a single diffusion region 505-1 shared by the gates 510-1 and 510-2 is shown for illustration purposes only. Different diffusion region configurations may also be employed without detracting from the merits of the present invention.

In FIG. 5A, gates 510 (i.e., 510-1, 510-2) are formed on a substrate 526, which may comprise a semiconductor (e.g. silicon) wafer. The diffusion region 505-1 is formed in the substrate 526. A gate 510 may have the same structure as the previously described gates 310. For example, as shown in FIG. 5A, a gate 510-1 may include spacers 543-1, a gate protective layer 544-1, a gate metal 541-1, and a gate polysilicon 542-1. The gate 510-1 also includes a gate oxide layer (not shown) between the gate polysilicon 542-1 and the substrate 526. The gate 510-1 may have additional layers of materials without detracting from the merits of the present invention. In one embodiment, the gate protective layer 544-1 and the spacers 543-1 comprise silicon nitride and the gate metal 541-1 comprises tungsten. Features of the gates 510-2 and 510-3 (see FIG. 5E), which are the same as those of the gate 510-1, are not labeled for clarity of illustration. Each gate 510 may have a total height of about 2300 Angstroms, for example. Each gate 510 may be part of a metal oxide semiconductor (MOS) transistor. A diffusion region 505 (i.e., 505-1, 505-2) may be the active region (e.g., source or drain) of a MOS transistor.

Still referring to FIG. 5A, an anti-reflective coating 563 is formed over the gates 510-1. In one embodiment, the anti-reflective coating 563 comprises the AR29 anti-reflective coating from Brewer Science, Inc. The anti-reflective coating 563 may be formed by spin on. A photoresist 562 is formed over the anti-reflective coating 563. The photoresist 562 defines a pattern 571 for etching the gate protective layer 544-1 to allow for subsequent electrical connection to the gate 510-1. The photoresist 562 may be formed by using a mask (e.g., see mask 361 of FIG. 3A) with the pattern 571.

In FIG. 5B, portions of or the entire gate protective layer 544-1 are removed to expose the gate metal 541-1. This may be performed by etching portions of the anti-reflective coating 563 on top of the gate protective layer 544-1 using a CHF3, CF4, Ar based etchant, then etching the gate protective layer 544-1 using a CH3F, O2, Ar based etchant. Because the spacers 543-1 and the gate protective layer 544-1 may comprise the same material (e.g. silicon nitride), portions or all of one side of a spacer 543-1 may also be etched away as a result. The anti-reflective coating 563 and the photoresist 562 are then removed after the etch step.

In FIG. 5C, a dielectric layer 551 is formed over the gates 510. In one embodiment, the dielectric layer 551 comprises PSG deposited by high density plasma chemical vapor deposition (HDP-CVD). The dielectric layer 551 is then planarized to a thickness of about 4000 Angstroms using chemical mechanical planarization (CMP). Thereafter, a capping layer 561 is formed over the dielectric layer 551. The capping layer 561 serves as stop layer for a subsequent contact and metal polish. In one embodiment, the capping layer 561 comprises silicon nitride deposited to a thickness of about 2100 Angstroms by plasma enhanced chemical vapor deposition (PECVD).

In FIG. 5D, a trench structure 572 is formed through the capping layer 561 and the dielectric layer 551. The trench structure 572 exposes the gate metal 541-1 and the diffusion region 505-1. As shown in FIG. 5E, the trench structure 572 also exposes a diffusion region 505-3 of another transistor that includes the gate 510-3. The trench structure 572 may be filled with a metal (e.g. tungsten) to electrically connect the gate 510-1, the diffusion region 505-1, and the diffusion region 505-3 together. FIG. 5F shows the trench structure 572 filled with a metal 573. As can be appreciated, the trench structure 572 may be used to electrically connect different nodes or features in the integrated circuit. The trench structure 572 serves as a shared contact structure that does not require overlying metal levels for connection. FIG. 6B shows a micrograph image of an integrated circuit with a trench structure 672 in accordance with an embodiment of the present invention. The trench structure 672 is similar to the just described trench structure 572. Note the absence of an oxide fence in FIG. 6B.

In one embodiment, the trench structure 572 comprises a local interconnect trench. The trench structure 572 may be formed by etching the capping layer 561, then etching the dielectric layer 551. In one embodiment, the dielectric layer 551 is etched using a self-aligned etch step. The etching of the dielectric layer 551 is self-aligned in that the etch is selective to the protective layer 544-2 of the gate 510-2. That is, the second etch step does not appreciably etch the protective layer 544-2. This advantageously makes the alignment of the trench layer less critical. The second etch step may thus be performed without inadvertently punching through the protective layer 544-2 (and thus inadvertently shorting the gate 510-2 when not called for). In one embodiment where the capping layer 561 and the gate protective layers 544 comprise silicon nitride and the dielectric layer 551 comprises PSG, the first etch step is performed using an etchant chemistry comprising CHF3, CF4, Ar while the second etch step is performed using an etchant chemistry comprising C4F6, O2, C2H2F4, CHF3.

Improved shared contact structures and methods of fabricating same have been disclosed. While specific embodiments of the present invention have been provided, it is to be understood that these embodiments are for illustration purposes and not limiting. Many additional embodiments will be apparent to persons of ordinary skill in the art reading this disclosure.

What is claimed is:

1. A method of forming a self-aligned shared contact structure in an integrated circuit, the method comprising:
providing a transistor, the transistor comprising a gate and a diffusion region, the gate comprising an electrically conductive layer and a protective layer serving as an electrical insulator formed over the electrically conductive layer;
removing at least a portion of the protective layer to expose the electrically conductive layer;
forming a dielectric layer over the transistor after removing at least the portion of the protective layer;
forming a trench through the dielectric layer, the trench exposing the electrically conductive layer and the diffusion region; and
filling the trench with a metal to electrically connect the electrically conductive layer and the diffusion region.

2. The method of claim 1 wherein the protective layer comprises silicon nitride.

3. The method of claim 2 wherein the trench is formed by etching the dielectric layer using an etch process that is selective to silicon nitride.

4. The method of claim 1 wherein the electrically conductive layer comprises a metal.

5. The method of claim 5 wherein the metal comprises tungsten.

6. The method of claim 1 wherein the trench further exposes another diffusion region and filling the trench with the metal electrically connects the electrically conductive layer, the diffusion region, and the other diffusion region.

7. The method of claim 1 further comprising:
before forming the trench, planarizing the dielectric layer and forming a capping layer over the planarized dielectric layer;
wherein the trench is formed through the dielectric layer and the capping layer.

8. The method of claim 7 wherein the capping layer comprises silicon nitride.

9. The method of claim 1 wherein the trench is formed by etching the dielectric layer using an etch process that does not appreciably etch a protective layer of a gate of another transistor.

10. An integrated circuit comprising:
a first transistor having a first gate and a first diffusion region;
a second transistor having a second gate and a second diffusion region;
a dielectric layer formed over the first and second transistors; and
a self-aligned trench structure formed through the dielectric layer, the trench structure being filled with a metal to electrically connect the first gate, the first diffusion region, and the second diffusion region together.

11. The integrated circuit of claim 10 wherein the trench structure has an L shape.

12. The integrated circuit of claim 10 wherein the first gate includes a gate metal layer that is electrically connected to the metal of the trench structure.

13. The integrated circuit of claim 12 wherein the metal layer comprises tungsten.

14. The integrated circuit of claim 10 further comprising:
a capping layer formed over the dielectric layer.

15. The integrated circuit of claim 14 wherein the capping layer comprises silicon nitride and the dielectric layer comprises phosphosilicate glass (PSG).

16. A method of forming a shared contact structure in an integrated circuit, the method comprising:
providing a transistor, the transistor comprising a gate and a diffusion region;
forming a dielectric layer over the transistor; and
electrically connecting the gate, the diffusion region, and another diffusion region using a trench structure formed in the dielectric layer, the trench structure being filled with a metal.

17. The method of claim 16 wherein the gate includes a gate metal that is electrically connected to the metal filling the trench structure.

18. The method of claim 17 further comprising:
prior to forming the dielectric layer over the transistor, removing at least a portion of a protective layer of the gate to expose the gate metal.

19. The method of claim 18 wherein the gate metal comprises tungsten and the protective layer comprises silicon nitride.

20. The method of claim 16 further comprising:
prior to electrically connecting the gate, the diffusion region, and the other diffusion region using the trench structure, forming a capping layer comprising silicon nitride over the dielectric layer.
